(19) United States
(12) Patent Application Publication
(10) Pub. No.: US 2024/0111919 A1
(43) Pub. Date: Apr. 4, 2024

(54) SYSTEM AND METHOD FOR GENERATING PREDICTIVE MODEL ASSOCIATED WITH ROTARY DEVICES

(71) Applicant: Chevron U.S.A. Inc., San Ramon, CA (US)

(72) Inventors: Devanand Ramchune, Humble, TX (US); Michael L. Levy, JR., Covington, LA (US); Jeanne Hoffman Waguespack, Metairie, LA (US); Mark Joseph Babbe, Houston, TX (US); Malina Elaine Majeran, Houston, TX (US)

(21) Appl. No.: 17/936,847

(22) Filed: Sep. 29, 2022

(51) Int. Cl. G06F 30/20; E21B 45/00; G08B 7/06; G08B 21/18

(52) U.S. Cl. CPC G06F 30/20; E21B 45/00; G08B 7/06; G08B 21/182; E21B 2200/20

(57) ABSTRACT

The disclosed embodiments include a system and method for generating a predictive model for determining whether a reamer has experienced significant wear. The system includes an information acquisition processor and a server. The information acquisition processor retrieves wellbore information, transmits the information to the server. The server generates and updates the predictive model that can predict whether the reamer has experienced wear

### FIELD OF THE DISCLOSURE

The present disclosure relates to a system and method for generating a predictive model configured to determine wear on a mechanical rotary device.

### BACKGROUND

Wellbores requires complex hole size of varying depth. For example, drilling with dual diameter is particularly challenging. Such wellbores are highly dependent on reamer durability. It is difficult to know where in the section a reamer starts to wear until the reamer is removed from the wellbore. At this point, the realization has come too late because the hole's diameter has been compromised. Much time is then incurred to re-ream the hole to open it back to plan diameter. It is difficult to recognize wear without removing the reamer form the wellbore.

These and other deficiencies exist. Therefore, there is a current demand for a unique system and method to determine when the reamer's durability has been compromised.

### SUMMARY OF THE DISCLOSURE

Aspects of the disclosed embodiments include a system and method for predicting the durability of a reamer.

Embodiments of the present disclosure provide a system for measuring the performance of a mechanical rotary device, the system comprising an information acquisition processor configured to retrieve at least a first set of information associated with a mechanical rotary device and transmit the information over a network; a data storage unit configured to store at least the first set of information associated with one or more mechanical rotary devices; a server configured to: receive, over a network, the one or more first sets of information associated with a mechanical rotary device, compare the first sets of information with one or more historical sets of information, determine, upon comparing the first sets of information with the historical sets of information, if there are one or more significant deviations from the historical sets of information; analyze, by a predetermined algorithm, the set of differences; generate, upon analyzing the set of differences, a predictive model, the predictive model further configured to determine whether the one or more mechanical rotary devices has experienced a change in durability; update, by a processor, the predictive model with one or more second sets of information associated with the mechanical rotary devices; determine, by the predictive model, whether one or more mechanical rotary device have experienced a change in durability; generate an auditory or visual alert; transmit the auditor or visual alert over a network; and a user device configured to receive the auditory or visual alert over a network.

Embodiments of the present disclosure provide a method for measuring the performance of a mechanical rotary device, the method comprising the steps of: retrieving, by a processor, information associated with a mechanical rotary device and transmit the information over a network; storing, by a data storage unit, at least one or more first sets of information associated with one or more mechanical rotary devices, the sets of information further comprising at least; receiving, over a network, one or more first sets of information associated with a mechanical rotary device, comparing, by the processor, the first sets of information with one or more historical sets of information, determining, upon comparing the sets of information with the historical sets of information, if there are significant deviations from the historical sets of information, analyzing, by a predetermined algorithm, the set of differences; generating, upon analyzing the set of differences, a predictive model, the predictive model further configured to determine whether the one or more mechanical rotary devices has experienced a change in durability; updating, by a processor, the predictive model with one or more second sets of information associated with the mechanical rotary devices; determining, by the predictive model, whether one or more mechanical rotary device have experienced a change in durability; generating, by the processor, an auditory or visual alert; and transmit, over a network, the auditor or visual alert over a network to a device.

Embodiments of the present disclosure provide a computer readable non-transitory medium comprising computer executable instructions that, when executed on a processor, perform procedures comprising the steps of: retrieving, by a processor, information associated with a mechanical rotary device and transmit the information over a network; storing, by a data storage unit, at least one or more first sets of information associated with one or more mechanical rotary devices, the sets of information further comprising at least; receiving, over a network, one or more first sets of information associated with a mechanical rotary device, comparing, by the processor, the first sets of information with one or more historical sets of information, determining, upon comparing the sets of information with the historical sets of information, if there are significant deviations from the historical sets of information, analyzing, by a predetermined algorithm, the set of differences; generating, upon analyzing the set of differences, a predictive model, the predictive model further configured to determine whether the one or more mechanical rotary devices has experienced a change in durability; updating, by a processor, the predictive model with one or more second sets of information associated with the mechanical rotary devices; determining, by the predictive model, whether one or more mechanical rotary device have experienced a change in durability; generating, by the processor, an auditory or visual alert; and transmit, over a network, the auditor or visual alert over a network to a device.

### BRIEF DESCRIPTION OF THE DRAWINGS

Further features of the disclosed systems and methods, and the advantages offered thereby, are explained in greater detail hereinafter with reference to specific example embodiments illustrated in the accompanying drawings.

In order to facilitate a fuller understanding of the present invention, reference is now made to the attached drawings. The drawings should not be construed as limiting the present invention, but are intended only to illustrate different aspects and embodiments of the invention.

FIG. 1 is a block diagram illustrating a system according to an exemplary embodiment.

FIG. 2 is a flowchart illustrating a method according to an exemplary embodiment.

FIG. 3 is graph illustrating a visualization according to an exemplary embodiment.

The invention relates generally to a system and method for generating a predictive model for predicting when a reamer has lost its required durability. By taking in a variety of inputs such as limitation bit size, reamer size, surface weight on the bit, downhole weight on the bit, surface torque, downhole torque, rate of penetration (ROP), and revolutions per minute (RPM). Using these inputs and comparing them against historical information, the predictive model can generate a score based on the likely durability of the reamer. If the durability has likely decreased, then a server can generate an alert to the user device.

This predictive model helps users predict when the reamer has lost significant durability. Thus, the user may fix or replace the reamer before continuing with the job. Furthermore, this saves the user time, money, confusion, and frustration.

### DETAILED DESCRIPTION

Exemplary embodiments of the invention will now be described in order to illustrate various features of the invention. The embodiments described herein are not intended to be limiting as to the scope of the invention, but rather are intended to provide examples of the components, use, and operation of the invention.

Furthermore, the described features, advantages, and characteristics of the embodiments may be combined in any suitable manner. One skilled in the relevant art will recognize that the embodiments may be practiced without one or more of the specific features or advantages of an embodiment. In other instances, additional features and advantages may be recognized in certain embodiments that may not be present in all embodiments.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

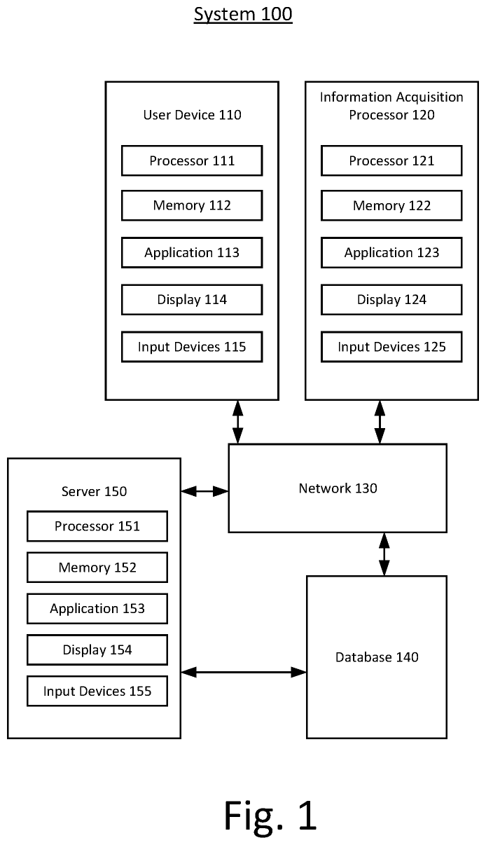

FIG. 1 illustrates a system according to an exemplary embodiment.

The system 100 can include a user device 110. The user device 110 may be a network-enabled computer device. Exemplary network-enabled computer devices include, without limitation, a server, a network appliance, a personal computer, a workstation, a phone, a handheld personal computer, a personal digital assistant, a thin client, a fat client, an Internet browser, a mobile device, a kiosk, a contactless card, an automatic teller machine (ATM), or other a computer device or communications device. For example, network-enabled computer devices may include an iPhone, iPod, iPad from Apple® or any other mobile device running Apple's iOS® operating system, any device running Microsoft's Windows® Mobile operating system, any device running Google's Android® operating system, and/or any other smartphone, tablet, or like wearable mobile device.

The user device 110 may include a processor 111, a memory 112, and an application 113. The processor 111 may be a processor, a microprocessor, or other processor, and the user device 110 may include one or more of these processors. The processor 111 may include processing circuitry, which may contain additional components, including additional processors, memories, error and parity/CRC checkers, data encoders, anti-collision algorithms, controllers, command decoders, security primitives and tamper-proofing hardware, as necessary to perform the functions described herein.

The processor 111 may be coupled to the memory 112. The memory 112 may be a read-only memory, write-once read-multiple memory or read/write memory, e.g., RAM, ROM, and EEPROM, and the user device 110 may include one or more of these memories. A read-only memory may be factory programmable as read-only or one-time programmable. One-time programmability provides the opportunity to write once then read many times. A write-once read-multiple memory may be programmed at a point in time after the memory chip has left the factory. Once the memory is programmed, it may not be rewritten, but it may be read many times. A read/write memory may be programmed and re-programed many times after leaving the factory. It may also be read many times. The memory 112 may be configured to store one or more software applications, such as the application 113, and other data, such as user's private data and financial account information.

The application 113 may comprise one or more software applications, such as a mobile application and a web browser, comprising instructions for execution on the user device 110. In some examples, the user device 110 may execute one or more applications, such as software applications, that enable, for example, network communications with one or more components of the system 100, transmit and/or receive data, and perform the functions described herein. Upon execution by the processor 111, the application 113 may provide the functions described in this specification, specifically to execute and perform the steps and functions in the process flows described below. Such processes may be implemented in software, such as software modules, for execution by computers or other machines. The application 113 may provide graphical user interfaces (GUIs) through which a user may view and interact with other components and devices within the system 100. The GUIs may be formatted, for example, as web pages in HyperText Markup Language (HTML), Extensible Markup Language (XML) or in any other suitable form for presentation on a display device depending upon applications used by users to interact with the system 100.

The user device 110 may further include a display 114 and input devices 115. The display 114 may be any type of device for presenting visual information such as a computer monitor, a flat panel display, and a mobile device screen, including liquid crystal displays, light-emitting diode displays, plasma panels, and cathode ray tube displays. The input devices 115 may include any device for entering information into the user device 110 that is available and supported by the user device 110, such as a touch-screen, keyboard, mouse, cursor-control device, touch-screen, microphone, digital camera, video recorder or camcorder. These devices may be used to enter information and interact with the software and other devices described herein.

The system 110 can include a information acquisition processor 120. The information acquisition processor 120 may be a network-enabled computer device. Exemplary network-enabled computer devices include, without limitation, a server, a network appliance, a personal computer, a workstation, a phone, a handheld personal computer, a personal digital assistant, a thin client, a fat client, an Internet browser, a mobile device, a kiosk, a contactless card, an automatic teller machine (ATM), or other a computer device or communications device. For example, network-enabled computer devices may include an iPhone, iPod, iPad from Apple® or any other mobile device running Apple's iOS® operating system, any device running Microsoft's Windows® Mobile operating system, any device running Google's Android® operating system, and/or any other smartphone, tablet, or like wearable mobile device.

The information acquisition processor 120 may include a processor 121, a memory 122, and an application 123. The processor 121 may be a processor, a microprocessor, or other processor, and the information acquisition processor 120 may include one or more of these processors. The processor 121 may include processing circuitry, which may contain additional components, including additional processors, memories, error and parity/CRC checkers, data encoders, anti-collision algorithms, controllers, command decoders, security primitives and tamper-proofing hardware, as necessary to perform the functions described herein.

The processor 121 may be coupled to the memory 122. The memory 122 may be a read-only memory, write-once read-multiple memory or read/write memory, e.g., RAM, ROM, and EEPROM, and the information acquisition processor 120 may include one or more of these memories. A read-only memory may be factory programmable as read-only or one-time programmable. One-time programmability provides the opportunity to write once then read many times. A write-once read-multiple memory may be programmed at a point in time after the memory chip has left the factory. Once the memory is programmed, it may not be rewritten, but it may be read many times. A read/write memory may be programmed and re-programed many times after leaving the factory. It may also be read many times. The memory 122 may be configured to store one or more software applications, such as the application 123, and other data, such as user's private data and financial account information.

The application 123 may comprise one or more software applications, such as a mobile application and a web browser, comprising instructions for execution on the information acquisition processor 120. In some examples, the information acquisition processor 120 may execute one or more applications, such as software applications, that enable, for example, network communications with one or more components of the system 100, transmit and/or receive data, and perform the functions described herein. Upon execution by the processor 121, the application 123 may provide the functions described in this specification, specifically to execute and perform the steps and functions in the process flows described below. Such processes may be implemented in software, such as software modules, for execution by computers or other machines. The application 123 may provide graphical user interfaces (GUIs) through which a user may view and interact with other components and devices within the system 100. The GUIs may be formatted, for example, as web pages in HyperText Markup Language (HTML), Extensible Markup Language (XML) or in any other suitable form for presentation on a display device depending upon applications used by users to interact with the system 100.

The information acquisition processor 120 may further include a display 124 and input devices 125. The display 124 may be any type of device for presenting visual information such as a computer monitor, a flat panel display, and a mobile device screen, including liquid crystal displays, light-emitting diode displays, plasma panels, and cathode ray tube displays. The input devices 125 may include any device for entering information into the information acquisition processor 120 that is available and supported by the information acquisition processor 120, such as a touch-screen, keyboard, mouse, cursor-control device, touch-screen, microphone, digital camera, video recorder or camcorder. These devices may be used to enter information and interact with the software and other devices described herein.

The system 100 can include a network 130. System 100 may include one or more networks 130. In some examples, the network 130 may be one or more of a wireless network, a wired network or any combination of wireless network and wired network, and may be configured to connect the user device 110, the server 150, and the database 140. For example, the network 130 may include one or more of a fiber optics network, a passive optical network, a cable network, an Internet network, a satellite network, a wireless local area network (LAN), a Global System for Mobile Communication, a Personal Communication Service, a Personal Area Network, Wireless Application Protocol, Multimedia Messaging Service, Enhanced Messaging Service, Short Message Service, Time Division Multiplexing based systems, Code Division Multiple Access based systems, D-AMPS, Wi-Fi, Fixed Wireless Data, IEEE 802.11b, 802.15.1, 802.11n and 802.11g, Bluetooth, NFC, Radio Frequency Identification (RFID), Wi-Fi, and/or the like.

In addition, the network 130 may include, without limitation, telephone lines, fiber optics, IEEE Ethernet 902.3, a wide area network, a wireless personal area network, a LAN, or a global network such as the Internet. In addition, the network 130 may support an Internet network, a wireless communication network, a cellular network, or the like, or any combination thereof. The network 130 may further include one network, or any number of the exemplary types of networks mentioned above, operating as a stand-alone network or in cooperation with each other. The network 130 may utilize one or more protocols of one or more network elements to which they are communicatively coupled. The network 130 may translate to or from other protocols to one or more protocols of network devices. Although the network 130 is depicted as a single network, it should be appreciated that according to one or more examples, the network 130 may comprise a plurality of interconnected networks, such as, for example, the Internet, a service provider's network, a cable television network, corporate networks, such as credit card association networks, and home networks. The network 130 may further comprise, or be configured to create, one or more front channels, which may be publicly accessible and through which communications may be observable, and one or more secured back channels, which may not be publicly accessible and through which communications may not be observable.

System 100 may include a database 140. The database 140 may be one or more databases configured to store data, including without limitation, private data of users, financial accounts of users, identities of users, transactions of users, and certified and uncertified documents. The database 140 may comprise a relational database, a non-relational database, or other database implementations, and any combination thereof, including a plurality of relational databases and non-relational databases. In some examples, the database 140 may comprise a desktop database, a mobile database, or an in-memory database. Further, the database 140 may be hosted internally by the server 150 or may be hosted externally of the server 140, such as by a server, by a cloud-based platform, or in any storage device that is in data communication with the server 150.

System 100 may include a server 150. The server 150 may be a network-enabled computer device. Exemplary network-enabled computer devices include, without limitation, a server, a network appliance, a personal computer, a workstation, a phone, a handheld personal computer, a personal digital assistant, a thin client, a fat client, an Internet browser, a mobile device, a kiosk, a contactless card, or other a computer device or communications device. For example, network-enabled computer devices may include an iPhone, iPod, iPad from Apple® or any other mobile device running Apple's iOS® operating system, any device running Microsoft's Windows® Mobile operating system, any device running Google's Android® operating system, and/or any other smartphone, tablet, or like wearable mobile device.

The server 150 may include a processor 151, a memory 152, and an application 153. The processor 151 may be a processor, a microprocessor, or other processor, and the server 130 may include one or more of these processors. The processor 151 may include processing circuitry, which may contain additional components, including additional processors, memories, error and parity/CRC checkers, data encoders, anti-collision algorithms, controllers, command decoders, security primitives and tamper-proofing hardware, as necessary to perform the functions described herein.

The processor 151 may be coupled to the memory 152. The memory 152 may be a read-only memory, write-once read-multiple memory or read/write memory, e.g., RAM, ROM, and EEPROM, and the server 150 may include one or more of these memories. A read-only memory may be factory programmable as read-only or one-time programmable. One-time programmability provides the opportunity to write once then read many times. A write-once read-multiple memory may be programmed at a point in time after the memory chip has left the factory. Once the memory is programmed, it may not be rewritten, but it may be read many times. A read/write memory may be programmed and re-programed many times after leaving the factory. It may also be read many times. The memory 152 may be configured to store one or more software applications, such as the application 153, and other data, such as user's private data and financial account information.

The application 153 may comprise one or more software applications comprising instructions for execution on the server 150. In some examples, the server 150 may execute one or more applications, such as software applications, that enable, for example, network communications with one or more components of the system 100, transmit and/or receive data, and perform the functions described herein. Upon execution by the processor 151, the application 153 may provide the functions described in this specification, specifically to execute and perform the steps and functions in the process flows described below. For example, the application 153 may be executed to perform receiving web form data from the user device 110 and masking private data received from the user device 110. Such processes may be implemented in software, such as software modules, for execution by computers or other machines. The application 153 may provide GUIs through which a user may view and interact with other components and devices within the system 100. The GUIs may be formatted, for example, as web pages in HyperText Markup Language (HTML), Extensible Markup Language (XML) or in any other suitable form for presentation on a display device depending upon applications used by users to interact with the system 100.

The server 150 may further include a display 154 and input devices 155. The display 154 may be any type of device for presenting visual information such as a computer monitor, a flat panel display, and a mobile device screen, including liquid crystal displays, light-emitting diode displays, plasma panels, and cathode ray tube displays. The input devices 153 may include any device for entering information into the server 150 that is available and supported by the server 150, such as a touch-screen, keyboard, mouse, cursor-control device, touch-screen, microphone, digital camera, video recorder or camcorder. These devices may be used to enter information and interact with the software and other devices described herein.

In some examples, exemplary procedures in accordance with the present disclosure described herein can be performed by a processing arrangement and/or a computing arrangement (e.g., computer hardware arrangement). Such processing/computing arrangement can be, for example entirely or a part of, or include, but not limited to, a computer/processor that can include, for example one or more microprocessors, and use instructions stored on a non-transitory computer-accessible medium (e.g., RAM, ROM, hard drive, or other storage device). For example, a computer-accessible medium can be part of the memory of the user device 110, the server 150, the network 130, and the database 140 or other computer hardware arrangement.

In some examples, a computer-accessible medium (e.g., as described herein, a storage device such as a hard disk, floppy disk, memory stick, CD-ROM, RAM, ROM, etc., or a collection thereof) can be provided (e.g., in communication with the processing arrangement). The computer-accessible medium can contain executable instructions thereon. In addition or alternatively, a storage arrangement can be provided separately from the computer-accessible medium, which can provide the instructions to the processing arrangement so as to configure the processing arrangement to execute certain exemplary procedures, processes, and methods, as described herein above, for example.

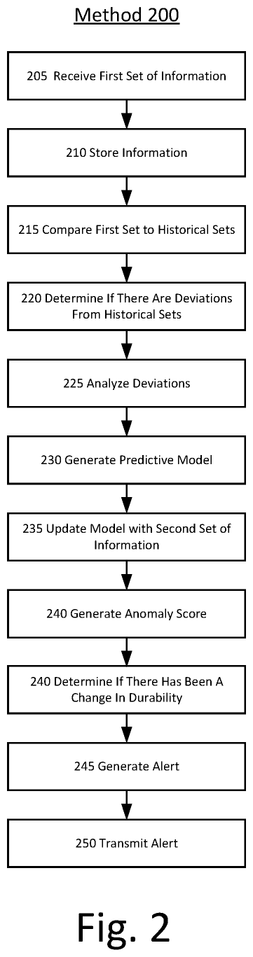

FIG. 2 is a flowchart illustrating a method according to exemplary embodiment.

In action 205, the server can receive a first set of information. The server can receive the information over a wired or wireless network. The server can receive the information from a user device, information, or some other processor. The information acquisition processor can be configured to receive and transmit information related to rotary devices or reamers associated with oil wells. This information can include without limitation bit size, reamer size, surface weight on the bit, downhole weight on the bit, surface torque, downhole torque, rate of penetration (ROP), and revolutions per minute (RPM). Other geographic and seismic information may be received and transmitted to the server. In action 210, the information can be stored in a database or data storage unit. This action can be performed by a processor associated with the information acquisition processor, user device, server, or some other processor. The database can be coupled to the server. Additionally, the processor may separate the sets of information into categories prior to storage and transmission. In action 215, the server compares the first set of information with historical sets of information. The historical sets can be retrieved from the database or the data storage unit. The historical sets may include or may not include the same categories of information as the first set. The historical sets can include information about the same or different well sites, wellbores, drill bits, geographic areas, teams, or other relevant drilling information. In action 220, the server can determine if there are any deviations between the first set of information and the historical sets of information. The deviations can be calculated by a processor associated with the server or by some predetermined algorithm. If there are deviations, in action 225, the processor can analyze these deviations. This analysis can include determining the scale of the deviation in relationship with other factors such as time, location, machinery being used, and other factors. Based on this analysis, in action 230 the server can generate a predictive model. The predictive model can be neural network or some other learning algorithm designed to determine whether the rotary device or reamer has experienced any significant wear.

A neural network is a series of algorithms that can, under predetermined training restrictions, recognize relationships between one or more variables. A neuron in a neural network is a mathematical function that collects and classifies information according to a specific form set by a user. Generally, a neural network can be divided into three main components: an input layer, a processing or hidden layer, and an output layer. The input layer comprises data sets chosen to be inserted into the neural network for analysis. The hidden layers include one or more neurons that can classify the inputs according to parameters set by the user. The hidden layers can comprise multiple successive layers, the first layer positioned immediately after the input layer and the last layer positioned immediately before the output layer. The hidden layer immediately after the input layer may be connected to the input layer via a predetermined weight or emphasis. These weights can be assigned according to the modeler's agenda. Alternatively, the model itself can determine the optimal weights between layers such that a predetermined outcome, margin of error, or minimum data point is achieved.

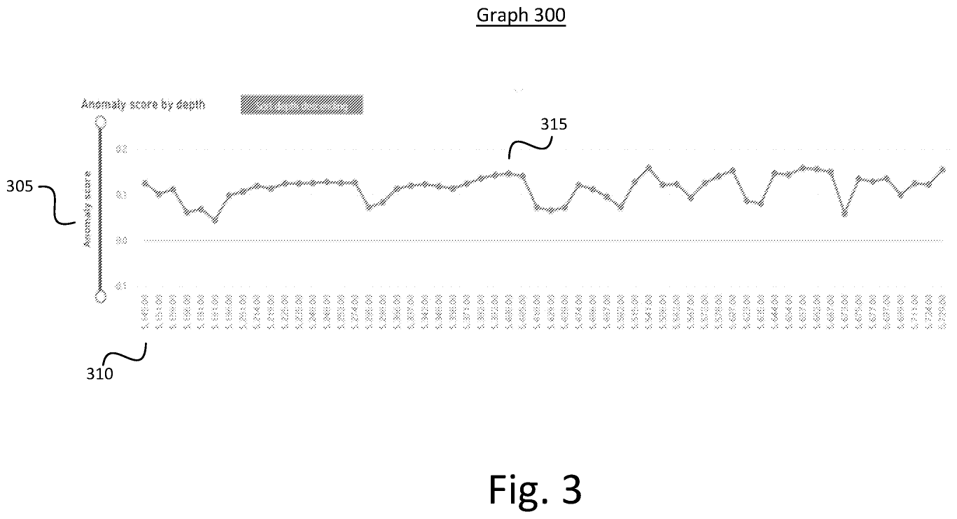

In action 235, the server can update the model with a second set of information. This second set can contain similar to different categories as the first set of information. It is understood that the second set of information can contain information gathered after the first set of information. It is also understood that any number of sets of information can be used to update the predictive model. Based on the updated information, in action 240 the server can generate an anomaly score. Anomaly scores are discussed with further reference to FIG. 3. In action 240, the predictive model can determine whether the mechanical rotary device or reamer has experienced a change in durability. The change in durability can be surmised from one or more anomaly scores. If a change in durability has been found, then in action 245 the server can generate an auditory or visual alert. The server can transmit the alert to in action 250 to a user device where it can be displayed to a user.

The predictive models described herein can utilize a Bidirectional Encoder Representations from Transformers (BERT) models. BERT models utilize use multiple layers of so called “attention mechanisms” to process textual data and make predictions. These attention mechanisms effectively allow the BERT model to learn and assign more importance to words from the text input that are more important in making whatever inference is trying to be made.

The exemplary system, method and computer-readable medium can utilize various neural networks, such as convolutional neural networks (CNNs) or recurrent neural networks (RNNs), to generate the exemplary models. A CNN can include one or more convolutional layers (e.g., often with a subsampling step) and then followed by one or more fully connected layers as in a standard multilayer neural network. CNNs can utilize local connections, and can have tied weights followed by some form of pooling which can result in translation invariant features.

A RNN is a class of artificial neural network where connections between nodes form a directed graph along a sequence. This facilitates the determination of temporal dynamic behavior for a time sequence. Unlike feedforward neural networks, RNNs can use their internal state (e.g., memory) to process sequences of inputs. A RNN can generally refer to two broad classes of networks with a similar general structure, where one is finite impulse and the other is infinite impulse. Both classes of networks exhibit temporal dynamic behavior. A finite impulse recurrent network can be, or can include, a directed acyclic graph that can be unrolled and replaced with a strictly feedforward neural network, while an infinite impulse recurrent network can be, or can include, a directed cyclic graph that may not be unrolled. Both finite impulse and infinite impulse recurrent networks can have additional stored state, and the storage can be under the direct control of the neural network. The storage can also be replaced by another network or graph, which can incorporate time delays or can have feedback loops. Such controlled states can be referred to as gated state or gated memory, and can be part of long short-term memory networks (LSTMs) and gated recurrent units.

RNNs can be similar to a network of neuron-like nodes organized into successive “layers,” each node in a given layer being connected with a directed e.g., (one-way) connection to every other node in the next successive layer. Each node (e.g., neuron) can have a time-varying real-valued activation. Each connection (e.g., synapse) can have a modifiable real-valued weight. Nodes can either be (i) input nodes (e.g., receiving data from outside the network), (ii) output nodes (e.g., yielding results), or (iii) hidden nodes (e.g., that can modify the data en route from input to output). RNNs can accept an input vector x and give an output vector y. However, the output vectors are based not only by the input just provided in, but also on the entire history of inputs that have been provided in in the past.

For supervised learning in discrete time settings, sequences of real-valued input vectors can arrive at the input nodes, one vector at a time. At any given time step, each non-input unit can compute its current activation (e.g., result) as a nonlinear function of the weighted sum of the activations of all units that connect to it. Supervisor-given target activations can be supplied for some output units at certain time steps. For example, if the input sequence is a speech signal corresponding to a spoken digit, the final target output at the end of the sequence can be a label classifying the digit. In reinforcement learning settings, no teacher provides target signals. Instead, a fitness function, or reward function, can be used to evaluate the RNNs performance, which can influence its input stream through output units connected to actuators that can affect the environment. Each sequence can produce an error as the sum of the deviations of all target signals from the corresponding activations computed by the network. For a training set of numerous sequences, the total error can be the sum of the errors of all individual sequences.

The models described herein may be trained on one or more training datasets, each of which may comprise one or more types of data. In some examples, the training datasets may comprise previously-collected data, such as data collected from previous uses of the same type of systems described herein and data collected from different types of systems. In other examples, the training datasets may comprise continuously-collected data based on the current operation of the instant system and continuously-collected data from the operation of other systems. In some examples, the training dataset may include anticipated data, such as the anticipated future workloads, currently scheduled workloads, and planned future workloads, for the instant system and/or other systems. In other examples, the training datasets can include previous predictions for the instant system and other types of system, and may further include results data indicative of the accuracy of the previous predictions. In accordance with these examples, the predictive models described herein may be training prior to use and the training may continue with updated data sets that reflect additional information.

FIG. 3 is a graph of anomaly scores according to an exemplary embodiment.

The graph 300 illustrates an example of how an anomaly score is generated via a dashboard. The graph can include an axis 305 for the anomaly score and another axis 310 for time. The resulting graph 315 can depict the anomaly score over time. The server may generate an alert is response to the anomaly score reaching a certain level for a predetermined period of time. The anomaly score can be predetermined ratio of wellbore attributes. The graphical visualization can be generated by the processor associated with the server.

Although embodiments of the present invention have been described herein in the context of a particular implementation in a particular environment for a particular purpose, those skilled in the art will recognize that its usefulness is not limited thereto and that the embodiments of the present invention can be beneficially implemented in other related environments for similar purposes. The invention should therefore not be limited by the above described embodiments, method, and examples, but by all embodiments within the scope and spirit of the invention as claimed.

In the invention, various embodiments have been described with references to the accompanying drawings. It may, however, be evident that various modifications and changes may be made thereto, and additional embodiments may be implemented, without departing from the broader scope of the invention as set forth in the claims that follow. The invention and drawings are accordingly to be regarded in an illustrative rather than restrictive sense.

The invention is not to be limited in terms of the particular embodiments described herein, which are intended as illustrations of various aspects. Many modifications and variations can be made without departing from its spirit and scope. Functionally equivalent systems, processes and apparatuses within the scope of the invention, in addition to those enumerated herein, may be apparent from the representative descriptions herein. Such modifications and variations are intended to fall within the scope of the appended claims. The invention is to be limited only by the terms of the appended claims, along with the full scope of equivalents to which such representative claims are entitled.

It is further noted that the systems and methods described herein may be tangibly embodied in one or more physical media, such as, but not limited to, a compact disc (CD), a digital versatile disc (DVD), a floppy disk, a hard drive, read only memory (ROM), random access memory (RAM), as well as other physical media capable of data storage. For example, data storage may include random access memory (RAM) and read only memory (ROM), which may be configured to access and store data and information and computer program instructions. Data storage may also include storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium), where the files that comprise an operating system, application programs including, for example, web browser application, email application and/or other applications, and data files may be stored. The data storage of the network-enabled computer systems may include electronic information, files, and documents stored in various ways, including, for example, a flat file, indexed file, hierarchical database, relational database, such as a database created and maintained with software from, for example, Oracle® Corporation, Microsoft® Excel file, Microsoft® Access file, a solid state storage device, which may include a flash array, a hybrid array, or a server-side product, enterprise storage, which may include online or cloud storage, or any other storage mechanism. Moreover, the figures illustrate various components (e.g., servers, computers, processors, etc.) separately. The functions described as being performed at various components may be performed at other components, and the various components may be combined or separated. Other modifications also may be made.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, to perform aspects of the present invention.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions specified herein. These computer-readable program instructions may also be stored in a computer-readable storage medium that can direct a computer, a programmable data processing apparatus, and/or other devices to function in a manner, such that the computer readable storage medium having instructions stored therein comprises an article of manufacture including instructions which implement aspects of the functions specified herein.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions specified herein.

We claim:

1. A system for measuring the performance of a mechanical rotary device, the system comprising
an information acquisition processor configured to retrieve at least a first set of information associated with a mechanical rotary device and transmit the information over a network;
a data storage unit configured to store at least the first set of information associated with one or more mechanical rotary devices;
a server configured to:
receive, over a network, the one or more first sets of information associated with a mechanical rotary device,
compare the first sets of information with one or more historical sets of information,
determine, upon comparing the first sets of information with the historical sets of information, if there are one or more significant deviations from the historical sets of information;
analyze, by a predetermined algorithm, the set of differences;
generate, upon analyzing the set of differences, a predictive model, the predictive model further configured to determine whether the one or more mechanical rotary devices has experienced a change in durability;
update, by a processor, the predictive model with one or more second sets of information associated with the mechanical rotary devices;
determine, by the predictive model, whether one or more mechanical rotary device have experienced a change in durability;
generate an auditory or visual alert;
transmit the auditor or visual alert over a network; and
a user device configured to receive the auditory or visual alert over a network.

2. The system of claim 1, wherein the mechanical rotary device is at least one or more reamers associated with the drilling of an oil well.

3. The system of claim 1, wherein the first and second sets of information associated with the mechanical rotary device comprises at least bit size, reamer size, and surface weight on bit.

4. The system of claim 1, wherein the first and second sets of information associated with the mechanical rotary device comprises at least downhole weight on bit, surface torque, and downhole torque.

5. The system of claim 1, wherein the first and second sets of information associated with the mechanical rotary device comprises at least rate of penetration (ROP) and revolutions per minute (RPM).

6. The system of claim 1, wherein the predictive model is further configured to generate an anomaly score, the anomaly score comprising at least predetermined ratio of wellbore attributes.

7. The system of claim 6, wherein the processor is further configured to generate a graphical representation of the anomaly score over a predetermined time period.

8. The system of claim 6, wherein the server is further configured to generate a visual or auditory alert only in response to the anomaly score reaching a predetermined limit.

9. The system of claim 1, wherein the server, prior to generating a predictive model, is further configured to separate the one or more sets of information associated with one or more mechanical rotary devices into one or more predetermined categories.

10. A method for measuring the performance of a mechanical rotary device, the method comprising the steps of:
retrieving, by a processor, information associated with a mechanical rotary device and transmit the information over a network;
storing, by a data storage unit, at least one or more first sets of information associated with one or more mechanical rotary devices, the sets of information further comprising at least;
receiving, over a network, one or more first sets of information associated with a mechanical rotary device,
comparing, by the processor, the first sets of information with one or more historical sets of information,
determining, upon comparing the sets of information with the historical sets of information, if there are significant deviations from the historical sets of information,
analyzing, by a predetermined algorithm, the set of differences;
generating, upon analyzing the set of differences, a predictive model, the predictive model further configured to determine whether the one or more mechanical rotary devices has experienced a change in durability;
updating, by a processor, the predictive model with one or more second sets of information associated with the mechanical rotary devices;
determining, by the predictive model, whether one or more mechanical rotary device have experienced a change in durability;
generating, by the processor, an auditory or visual alert; and
transmit, over a network, the auditor or visual alert over a network to a device.

11. The method of claim 10, wherein the mechanical rotary device is at least one or more reamers associated with the drilling of an oil well.

12. The method of claim 10, wherein the information associated with the mechanical rotary device comprises at least bit size, reamer size, and surface weight on bit.

13. The method of claim 10, wherein the information associated with the mechanical rotary device comprises at least downhole weight on bit, surface torque, and downhole torque.

14. The method of claim 10, wherein the information associated with the mechanical rotary device comprises at least rate of penetration (ROP) and revolutions per minute (RPM).

15. The method of claim 10, wherein the predictive model is further configured to generate an anomaly score, the anomaly score comprising at least predetermined ratio of wellbore attributes.

16. The method of claim 10, wherein the server is further configured to generate a visual alert only in response to the anomaly score reaching a predetermined limit.

17. The method of claim 10, the server, prior to generating a predictive model, is further configured to separate the one or more sets of information associated with one or more mechanical rotary devices into one or more predetermined categories.

18. A computer readable non-transitory medium comprising computer executable instructions that, when executed on a processor, perform procedures comprising the steps of:
retrieving, by a processor, information associated with a mechanical rotary device and transmit the information over a network;
storing, by a data storage unit, at least one or more first sets of information associated with one or more mechanical rotary devices, the sets of information further comprising at least;
receiving, over a network, one or more first sets of information associated with a mechanical rotary device,
comparing, by the processor, the first sets of information with one or more historical sets of information,
determining, upon comparing the sets of information with the historical sets of information, if there are significant deviations from the historical sets of information,
analyzing, by a predetermined algorithm, the set of differences;
generating, upon analyzing the set of differences, a predictive model, the predictive model further configured to determine whether the one or more mechanical rotary devices has experienced a change in durability;
updating, by a processor, the predictive model with one or more second sets of information associated with the mechanical rotary devices;
determining, by the predictive model, whether one or more mechanical rotary device have experienced a change in durability;
generating, by the processor, an auditory or visual alert; and
transmit, over a network, the auditor or visual alert over a network to a device.

19. The computer-readable storage medium of claim 18, wherein the steps further comprise generating an anomaly score, the anomaly score comprising at least predetermined ratio of wellbore attributes.

20. The computer-readable storage medium of claim 18, wherein the steps further comprise generating a visual alert only in response to the anomaly score reaching a predetermined limit.
